(19) United States
(12) Patent Application Publication
(10) Pub. No.: US 2025/0243379 A1
(43) Pub. Date: Jul. 31, 2025

(54) REHEALABLE AND REWORKABLE ELECTRONIC PACKAGING MATERIALS

(71) Applicant: International Business Machines Corporation, Armonk, NY (US)

(72) Inventors: Teddie P. Magbitang, San Jose, CA (US); Rudy J. Wojtecki, San Jose, CA (US); Ishwar Singh, Sunnyvale, CA (US)

(21) Appl. No.: 18/426,404

(22) Filed: Jan. 30, 2024

(51) Int. Cl. C09D 163/00; C08G 59/24; C08G 59/68; C09D 5/26; H01L 23/00

(52) U.S. Cl. CPC C09D 163/00; C08G 59/24; C08G 59/686; C09D 5/26; H01L 24/29; H01L 24/98; H01L 2224/2919; H01L 2224/98

(57) ABSTRACT

A composition includes an underfill comprising a polymer having monomer units with substituted Diels-Alder moieties and ester moieties. A first process includes obtaining an underfill comprising a polymer having monomer units with substituted Diels-Alder moieties and ester moieties. A second process includes providing a mixture that includes a curing agent and a monomer comprising substituted Diels-Alder moieties and ester moieties. The second process also includes curing the mixture to form the underfill. A third process includes providing a semiconductor device that includes the underfill. A semiconductor device includes the underfill.

### BACKGROUND

The present disclosure relates to electronic packaging materials and, more specifically, to polymer underfills.

Various polymeric materials (e.g., adhesives, thermal interface materials, underfills) are used in the manufacture of semiconductor and microelectronic devices. For example, an underfill can be used in electronic packaging at a connection between a semiconductor chip and a board. When a semiconductor chip is connected to a board, electrical connections are made between electrical terminations on the chip and corresponding electrical terminations on the board. For example, these connections can be made using metallic or polymeric material that is applied in bumps (e.g., solder bumps) to the chip or board terminals. The resulting assembly can then be heated to reflow the metallic or polymeric material and solidify the connection. Gaps between a printed wiring board and connected components can be filled with the underfill, which can reinforce the interconnect and absorb stress from mechanical shock.

### SUMMARY

Various embodiments are directed to a composition comprising an underfill. The underfill comprises a polymer having monomer units with substituted Diels-Alder moieties and ester moieties. In some embodiments, the underfill also includes a filler. In further embodiments, the underfill may include a thermally latent base. The monomer units may have the following structure:

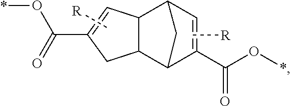

wherein each starred bond is to a carbon atom of the polymer and each R is an organic substituent. In some embodiments, the organic substituent comprises an alkyl group.

Additional embodiments are directed to a process that includes obtaining an underfill that comprises a polymer having monomer units with substituted Diels-Alder moieties and ester moieties. The underfill may be a composite material. In some embodiments, the process also includes healing a defect in the underfill by applying a thermal stimulus to the underfill. In further embodiments, the process can include removing the underfill from a surface by treating the polymer with a solution comprising reagents for depolymerization, such as an organic catalyst and an alcohol. The depolymerization may include a transesterification reaction. The underfill can be below at least one chip in a semiconductor device. In these instances, the process may include dissolving a layer of the underfill at a location of a selected chip from the at least one chip, removing the selected chip and the dissolved underfill from location, and connecting a new chip at the location. Further, the process may include applying a thermal stimulus to soften a layer of the underfill at a location of a selected chip from the at least one chip, removing the selected chip from the softened layer of the underfill, dissolving the layer of the underfill via transesterification, removing the dissolved underfill, and connecting a new chip at the location. In some embodiments, the process includes healing a defect in a layer of the underfill below a selected chip from the at least one chip by applying a localized thermal stimulus at the selected chip. In the underfill polymer, the monomer units may have the following structure:

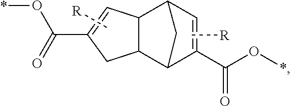

wherein each starred bond is to a carbon atom of the polymer, and each R is an organic substituent. The organic substituent may be an alkyl group.

Further embodiments are directed to a process that includes providing a mixture that comprises a curing agent and a monomer comprising substituted Diels-Alder moieties and ester moieties. The process also includes curing the mixture to form an underfill. The monomer may have the following structure:

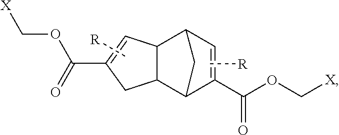

wherein each X is a moiety comprising a reactive group, and each R is an organic substituent. In some embodiments, each X is a glycidyl moiety.

Additional embodiments are directed to a process that includes providing a semiconductor device that includes the underfill. Further embodiments are directed to the semiconductor device containing the underfill. In some embodiments, the semiconductor device includes a multichip module in which the underfill is a layer below at least one chip in the multichip module.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1A is a flow diagram illustrating a process of providing an underfill material, according to some embodiments.

FIG. 1B is a flow diagram illustrating a process of reworking the underfill of FIG. 1A, according to some embodiments.

FIG. 1C is a flow diagram illustrating a process of rehealing the underfill of FIG. 1A, according to some embodiments.

FIG. 2 is a chemical reaction diagram illustrating a process of forming a monomer with ester moieties and thermally reversable Diels-Alder dimer moieties, according to some embodiments.

FIG. 3 is a chemical reaction diagram illustrating a process of forming a polymer for underfills or other packaging materials, according to some embodiments.

FIG. 4 is a chemical reaction diagram illustrating a process of rehealing the polymer illustrated in FIG. 3, according to some embodiments.

FIG. 5 is a chemical reaction diagram illustrating a process of depolymerizing the polymer of FIG. 3, according to some embodiments.

While the invention is amenable to various modifications and alternative forms, specifics thereof have been shown by way of example in the drawings, and will be described in detail. It should be understood, however, that the intention is not to limit the invention to the particular embodiments described. Instead, the intention is to cover all modifications, equivalents, and alternatives falling within the spirit and scope of the invention.

### DETAILED DESCRIPTION

Embodiments of the present invention are generally directed to electronic packaging materials and, more specifically, to epoxy-based underfill materials. While the present disclosure is not necessarily limited to such applications, various aspects of the disclosure may be appreciated through a discussion of examples using this context.

Although the present invention has been described in reference to specific embodiments, it should be understood that the invention is not limited to these examples only and that many variations of these embodiments may be readily envisioned by the skilled person after having read the present disclosure. The invention may thus further be described without limitation, and by way of example only, by the following embodiments.

Embodiment 1: a composition comprising an underfill, wherein the underfill comprises a polymer having monomer units with substituted Diels-Alder moieties and ester moieties. An advantage of this underfill may be that the Diels-Alder moieties can undergo reverse dimerization, and the ester moieties can participate in transesterification reactions.

Embodiment 2: the composition of embodiment 1, wherein the underfill further comprises a filler. This can advantageously facilitate thermal conductivity.

Embodiment 3: the composition of embodiment 1 or 2, wherein the underfill further comprises a thermally latent base. This may advantageously allow the underfill to be depolymerized by application of a heat stimulus.

Embodiment 4: the composition of any one of embodiments 1-3, wherein the monomer units have the following structure:

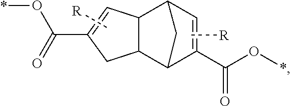

wherein each starred bond is to a carbon atom of the polymer and each R is an organic substituent. An advantage of this can be that the underfill properties may be tuned by varying the substituents and ester moieties.

Embodiment 5: the composition of embodiment 4, wherein the organic substituent comprises an alkyl group. An advantage of this may be that alkyl groups can be selected based on sterics and/or reactivity, allowing properties of the polymer to be varied.

Embodiment 6: a process comprising obtaining an underfill that comprises a polymer having monomer units with substituted Diels-Alder moieties and ester moieties. An advantage of this process may be that the Diels-Alder moieties can undergo reverse dimerization, and the ester moieties can participate in transesterification reactions.

Embodiment 7: the process of embodiment 6, wherein the underfill is a composite material. This can advantageously facilitate thermal conductivity.

Embodiment 8: the process of embodiment 6 or 7, further comprising healing a defect in the underfill by applying a thermal stimulus to the underfill. This can extend the lifetime of the underfill by repairing cracks, voids, and other defects.

Embodiment 9: the process of embodiment 6 or 7, further comprising removing the underfill from a surface by treating the polymer with a solution comprising reagents for depolymerization. This can advantageously allow reuse of the cleaned surface.

Embodiment 10: the process of embodiment 9, wherein the reagents comprise an organic catalyst and an alcohol. These reagents may advantageously allow the underfill to be removed without damaging the surface.

Embodiment 11: the process of embodiment 9 or 10, wherein the depolymerization comprises a transesterification reaction. An advantage of this can be that transesterification can be carried out using a variety of common reagents and reaction conditions.

Embodiment 12: the process of any one of embodiments 6-11, wherein the underfill is below at least one chip in a semiconductor device. This may extend the lifetime of the device because the underfill can be healed via thermal stimulus, which can improve the chip's connection and prevent cracks from propagating into components of the device. Additionally, by dissolving the underfill, a defective chip may be replaced.

Embodiment 13: the process of embodiment 12, further comprising dissolving a layer of the underfill at a location of a selected chip from the at least one chip, removing the selected chip and the dissolved underfill from location, and connecting a new chip at the location. This may extend the lifetime of a device when the selected chip is defective.

Embodiment 14: the process of embodiment 12, further comprising applying a thermal stimulus to soften a layer of the underfill at a location of a selected chip from the at least one chip, removing the selected chip from the softened layer of the underfill, dissolving the layer of the underfill via transesterification, removing the dissolved underfill, and connecting a new chip at the location. This may extend the lifetime of a device when the selected chip is defective. Applying the thermal stimulus may facilitate easy removal of the defective chip.

Embodiment 15: the process of embodiment 12, further comprising healing a defect in a layer of the underfill below a selected chip from the at least one chip by applying a localized thermal stimulus at the selected chip. This can extend the lifetime of the underfill by repairing cracks, voids, and other defects.

Embodiment 16: the process of any one of embodiments 6-15, wherein the monomer units have the following structure:

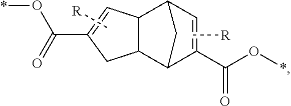

wherein each starred bond is to a carbon atom of the polymer, and each R is an organic substituent. An advantage of this can be that the provided underfill's properties may be tuned by varying the substituents and ester moieties.

Embodiment 17: the process of embodiment 16, wherein the organic substituent is an alkyl group. An advantage of this may be that alkyl groups can be selected based on sterics and/or reactivity, allowing properties of the polymer to be varied.

Embodiment 18: a process comprising providing a mixture, the mixture comprising a curing agent and a monomer comprising substituted Diels-Alder moieties and ester moieties, and curing the mixture to form an underfill. An advantage of this process may be that the Diels-Alder moieties can undergo reverse dimerization, and the ester moieties can participate in transesterification reactions.

Embodiment 19: the process of embodiment 18, wherein the monomer has the following structure:

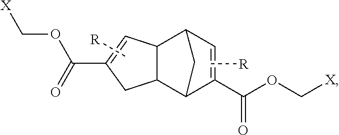

wherein each X is a moiety comprising a reactive group, and each R is an organic substituent. An advantage of this can be that the monomer's properties may be tuned by varying the substituents and ester moieties.

Embodiment 20: the process of embodiment 19, wherein each X is a glycidyl moiety. Glycidyl moieties may advantageously allow formation of an epoxy-based underfill.

Embodiment 21: a process comprising providing a semiconductor device comprising an underfill, the underfill comprising a polymer having monomer units with substituted Diels-Alder moieties and ester moieties. An advantage of this process may be that the Diels-Alder moieties can undergo reverse dimerization, and the ester moieties can participate in transesterification reactions.

Embodiment 22: the process of embodiment 21, wherein the monomer units have the following structure:

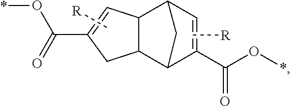

wherein each starred bond is to a carbon atom of the polymer, and each R is an organic substituent. An advantage of this can be that the underfill's properties may be tuned by varying the substituents and ester moieties.

Embodiment 23: a semiconductor device comprising an underfill comprising a polymer, wherein the polymer comprises monomer units with substituted Diels-Alder moieties and ester moieties. An advantage of this underfill may be that the Diels-Alder moieties can undergo reverse dimerization, and the ester moieties can participate in transesterification reactions.

Embodiment 24: the semiconductor device of embodiment 23, wherein the monomer units have the following structure:

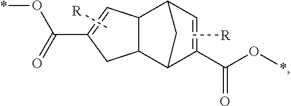

wherein each starred bond is to a carbon atom of the polymer, and each R is an organic substituent. An advantage of this can be that the underfill's properties may be tuned by varying the substituents and ester moieties.

Embodiment 25: the semiconductor device of embodiment 23 or 24, wherein the semiconductor device comprises a multichip module, and wherein the underfill is a layer below at least one chip in the multichip module. This can advantageously extend the lifetime of the semiconductor device because the underfill can be rehealed to repair defects and prevent the defects from propagating into the device. The lifetime of the device can also be extended by depolymerizing the underfill in order to replace a defective chip.

Various embodiments of the present disclosure are described herein with reference to the related drawings, where like numbers refer to the same component. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “over,” “positioned on,” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

As used herein, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

Unless otherwise noted, ranges (e.g., time, concentration, temperature, etc.) indicated herein include both endpoints and all numbers between the endpoints. Unless specified otherwise, the use of a tilde (˜) or terms such as “about,” “substantially,” “approximately,” “slightly less than,” and variations thereof are intended to include the degree of error associated with measurement of the particular quantity based upon the equipment available at the time of filing the application. For example, “about” can include a range of +8% or 5%, or 2% of a given value, range of values, or endpoints of one or more ranges of values. Unless otherwise indicated, the use of terms such as these in connection with a range applies to both ends of the range (e.g., “approximately 1 g-5 g” should be interpreted as “approximately 1 g-approximately 5 g”) and, in connection with a list of ranges, applies to each range in the list (e.g., “about 1 g-5 g, 5 g-10 g, etc.” should be interpreted as “about 1 g-about 5 g, about 5 g-about 10 g, etc.”).

As used herein the term “aliphatic” encompasses the terms alkyl, alkenyl, or alkynyl. Aliphatic radicals or groups may have any degree of saturation, such as groups having only single carbon-carbon bonds (“alkyl” or “alkylene”), groups having one or more double carbon-carbon bonds (“alkenyl”), radicals having one or more triple carbon-carbon bonds (“alkynyl”), and groups having a mixture of single, double and/or triple carbon-carbon bonds.

As used herein, an “alkyl” group refers to a saturated aliphatic hydrocarbon group containing at least one carbon atom (e.g., C1-C4, C1-C6, or C1-C8 alkyls). An alkyl group can be straight, branched, cyclic, or any combination thereof. Unless specifically limited otherwise, the term “alkyl,” as well as derivative terms such as “alkoxy” and “thioalkyl,” as used herein, include within their scope, straight chain, branched chain, and cyclic moieties. If the alkyl radical is further bonded to another atom, it becomes an alkylene radical or alkylene group. In other words, the term “alkylene” also refers to a divalent linear or branched alkyl. For example, —CH₂CH₃ is an ethyl, while —CH₂CH₂— is an ethylene. The term “alkylene” alone or as part of another substituent refers to a saturated linear or branched divalent hydrocarbon radical obtained by removing two hydrogen atoms from a single carbon atom or two different carbon atoms of a starting alkane.

Examples of alkyl radicals/moieties or alkyl groups include methyl, ethyl, propyl, 1-methylethyl, butyl, 1-methylpropyl, 2-methylpropyl, 1,1-dimethylethyl, pentyl, 1-methylbutyl, 2-methylbutyl, 3-methylbutyl, 2,2-dimethylpropyl, 1-ethylpropyl, hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, and 1-ethyl-2-methylpropyl. The alkyl group or alkylene group as defined above may be unsubstituted or substituted with one or more substituents as set forth below.

As used herein, the term “cyclic” refers to a ring compound or group comprising at least three carbon atoms and the bonds between pairs of adjacent atoms may all be of the type designated single bonds (involving two electrons), or some of them may be double or triple bonds (with four or six electrons, respectively). Examples of cyclic aliphatic groups can include phenyl, saturated cycloalkyls (e.g., cyclopropyl, cyclobutyl, cyclopentyl, or cyclohexyl), etc.

As used herein, the term “amine” or “amino” includes compounds where a nitrogen atom is covalently bonded to at least one carbon or heteroatom. The term “amine” or “amino” includes —NH₂ and also includes substituted moieties. The term includes “alkyl amino” which comprises groups and compounds wherein the nitrogen is bound to at least one additional alkyl group (e.g., a secondary or tertiary amine). As used herein, the term “imino” group or residue means the bivalent group ═NR, wherein R in this context represents either H or an alkyl group as defined herein. As used herein, the term “imide” refers to groups or compounds having a nitrogen atom covalently bonded to two carbonyl groups. As used herein, the term “furan” refers to groups or compounds having a five-membered aromatic ring containing four carbon atoms and one oxygen atom.

As described herein, compounds of the present disclosure can optionally be substituted with one or more substituents, such as are illustrated generally above, or as exemplified by particular classes, subclasses, and species of the present disclosure. As described herein, any of the above moieties or those introduced below can be optionally substituted with one or more substituents described herein.

The term “substituted” in the context of the present disclosure means that one or more hydrogen atoms of the indicated radical or group is/are independently replaced by the same or a different substituent(s). Additionally, the term “substituted” specifically provides for one or more, e.g., two, three, or more, substituents commonly used in the art. However, it is generally known that the substituents should be selected so that they do not adversely affect the useful properties of the compound or its function.

Suitable substituents in the context of the present disclosure may include, in some embodiments, halogen groups, perfluoroalkyl groups, perfluoroalkoxy groups, alkyl groups, alkenyl groups, alkynyl groups, hydroxy groups, oxo groups, mercapto groups, alkylthio groups, alkoxy groups, aryl or heteroaryl groups, aryloxy groups or heteroaryloxy groups, arylalkyl or heteroarylalkyl groups, arylalkoxy or heteroarylalkoxy groups, amino groups, alkyl and dialkylamino groups, carbamoyl groups, alkylcarbonyl groups, carboxyl groups, alkoxycarbonyl groups, alkylaminocarbonyl groups, dialkylaminocarbonyl groups, arylcarbonyl groups, aryloxycarbonyl groups, alkylsulfonyl groups, arylsulfonyl groups, cycloalkyl groups, cyano groups, C1 to C6 alkylthio groups, arylthio groups, nitro groups, keto groups, acyl groups, boronate or boronyl groups, phosphate or phosphonyl groups, sulfamyl groups, sulfonyl groups, sulfinyl groups, and combinations thereof.

In further embodiments, substituents or substituent groups may include halogen, hydroxyl, alkyl, alkenyl, alkynyl, alkoxyl, —NH₂, amino (primary, secondary, or tertiary), nitro, thiol, thioether, imine, cyano, amido, phosphonato, phosphine, carboxyl, thiocarbonyl, sulfonyl, sulfonamide, ketone, aldehyde, ester, acetyl, acetoxy, carbamoyl, oxygen (O); haloalkyl (e.g., trifluoromethyl); aminoacyl and aminoalkyl, carbocyclic cycloalkyl, which may be monocyclic or fused or non-fused polycyclic (e.g., cyclopropyl, cyclobutyl, cyclopentyl, or cyclohexyl), or a heterocycloalkyl, which may be monocyclic or fused or non-fused polycyclic (e.g., pyrrolidinyl, piperidinyl, piperazinyl, morpholinyl, or thiazinyl), carbocyclic or heterocyclic, monocyclic or fused or non-fused polycyclic aryl (e.g., phenyl, naphthyl, pyrrolyl, indolyl, furanyl, thiophenyl, imidazolyl, oxazolyl, isoxazolyl, thiazolyl, triazolyl, tetrazolyl, pyrazolyl, pyridinyl, quinolinyl, isoquinolinyl, acridinyl, pyrazinyl, pyridazinyl, pyrimidinyl, benzimidazolyl, benzothiophenyl, or benzofuranyl), —CO₂CH₃, —CONH₂, —OCH₂CONH₂; —SO₂NH₂, —OCHF₂, —CF₃, —OCF₃.

Modifications or derivatives of the compounds disclosed throughout this specification are contemplated as being useful with the methods and compositions of the present disclosure. Derivatives may be prepared and the properties of such derivatives may be assayed for their desired properties by any method known to those of skill in the art. In certain aspects, “derivative” refers to a chemically modified compound that still retains the desired effects of the compound prior to the chemical modification.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

It should also be understood that material compounds will be described in terms of listed elements, e.g., SiN, or SiGe. These compounds include different proportions of the elements within the compound, e.g., SiGe includes SiₓGe₍₁₋ₓ₎ where x is less than or equal to 1, and the like. In addition, other elements can be included in the compound and still function in accordance with the present principles. The compounds with additional elements will be referred to herein as alloys.

Turning now to an overview of technologies that are more specifically relevant to aspects of the present disclosure, in general, electronic packaging components of semiconductor and microelectronic devices can include a variety of polymeric materials, such as underfills, thermal interface materials (TIMs), adhesives, pastes, laminates, etc. For example, gaps between a printed wiring board and connected components (e.g., semiconductor chips) can be filled with an underfill in order to reinforce connections and absorb stress from mechanical shock. Epoxy-based polymeric materials are commonly used in these packaging materials. Epoxy-based materials referred to as “two-part epoxies” include an epoxy compound/monomer (part A) that is mixed with a hardening or curing agent (part B), such as a primary amine. However, cracks can form in underfills and other components because of, for example, the effect of elevated temperatures on materials with different coefficients of thermal expansion (CTEs). These cracks can propagate into surrounding components, leading to device unreliability or failure. For example, cracks in commonly used epoxy-based capillary underfills can reduce sidewall adhesion and propagate into a device's interlayer dielectric (ILD), solder, solder mask, etc.

Embodiments of the present disclosure may improve the yield and lifetime of packages and allow scaling of MCMs. In some embodiments, an epoxy-based material (e.g., a capillary underfill) is provided, which includes a polymer that can be formed by reacting an epoxy compound having ester moieties and substituted Diels-Alder dimer moieties (e.g., dicyclopentadiene moieties) with an amine curing agent. The epoxy-based material may include a mixture of the polymer and additional material(s), such as a filler (e.g., silica particles), a radical inhibitor, etc. In some embodiments, properties of the material can be tuned by selection of substituents on the Diels-Alder dimer moieties, ester groups, amine curing agent, and/or filler (e.g., size and composition of particles, weight percent (wt. %) filler in composite).

The disclosed epoxy-based material can be rehealable and reworkable. Healing of fractures, voids, and other defects in components such as TIMs, underfills, adhesives, etc., that include the epoxy-based material may be accomplished by application of heat to the thermally reversible Diels-Alder dimer moieties of the polymer. In some embodiments, depolymerization and removal of the material from a substrate can be carried out by treatment with a solution containing reagents for depolymerization. These reagents can react with the ester moieties of the polymer in a variety of ways. This can allow removal of defective chips without grinding or other methods that can damage an underlying laminate and/or other device components.

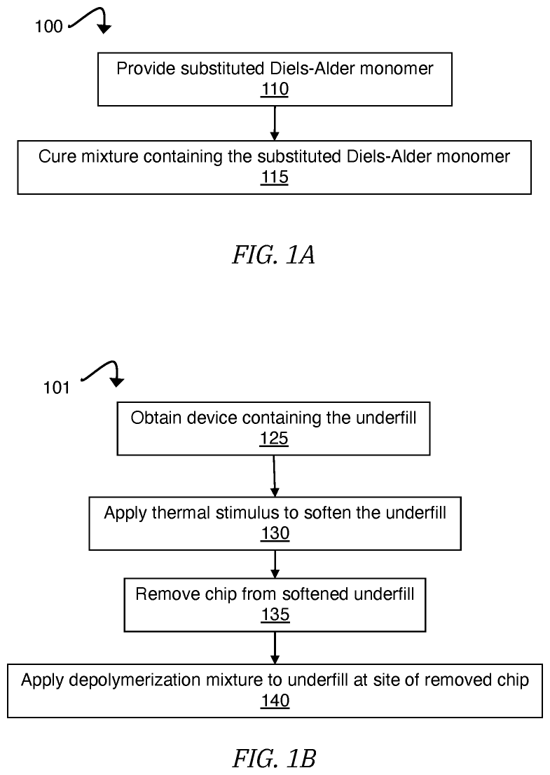

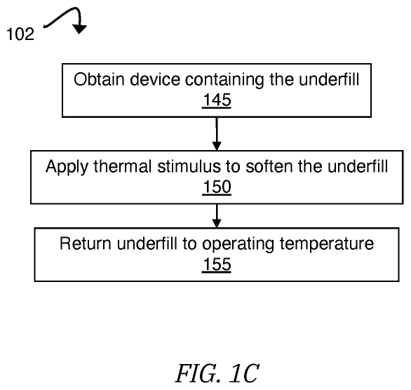

Referring now to the drawings, in which like numerals represent the same or similar elements, FIG. 1A is a flow diagram illustrating a process 100 of providing an underfill material, according to some embodiments. A monomer with ester moieties and R-substituted thermally reversable Diels-Alder dimer moieties can be provided. This is illustrated at operation 110. The monomer can have the following structure:

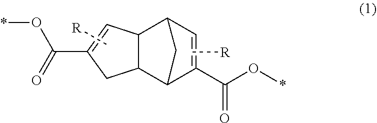

wherein each starred bond is to a carbon atom of a moiety having polymerizable reactive groups, and each R group is a organic substituent. Examples of the polymerizable reactive groups can include epoxy, styrene, α,β-unsaturated carbonyl, aziridine, dicarbonyl, etc. In some embodiments, the polymerizable reactive groups may include pH- or light-responsive moieties, which may allow polymerization and/or depolymerization to occur in response to pH changes or light exposure.

Examples of the R groups in Formula 1 can be hydrocarbons such as methyl, ethyl, propyl, butyl, etc., or other optionally substituted aliphatic groups. In some embodiments, the R groups can selected based on their steric and/or reactive properties in order to tune properties of the monomer and/or the underfill formed in process 100. For example, physical properties of the underfill, including an amount of softening in response to a thermal stimulus, may be adjusted by using branched or linear hydrocarbon chains as the R groups. In some embodiments, the R groups can be selected to tune the solubility of the substituted Diels-Alder monomer. Additionally, the R groups may affect polymerization of the monomers and may be involved in crosslinking (see below). Monomers illustrated by Formula 1 are also referred to herein as “substituted Diels-Alder monomers”.

Properties of the underfill may also be tuned by selection of ester groups (moieties at the starred bonds). For example, the selection of reactive groups on these moieties can determine the type of polymer formed from the substituted Diels-Alder monomers. In some embodiments, the monomers have substituents with terminal epoxy groups. This is discussed in greater detail below. Properties of the underfill may also be tuned by selection of other substituents on the starred bond moieties, as will be understood by persons of ordinary skill in the art.

A mixture containing the substituted Diels-Alder monomer can be cured. This is illustrated at operation 115. The mixture may be an underfill applied surrounding solder balls between a chip and laminate. The curing can include polymerizing the Diels-Alder monomer with a curing agent at any temperature appropriate for the monomer/curing agent. In some embodiments, the polymerization involves crosslinking of the R groups shown in Formula 1. For example, curing may take place at temperatures of about 60° C., 90° C., 100° C., 120° C., etc., depending on the reagent selection. When the starred bonds in Formula 1 are to moieties with epoxy groups, an amine curing agent may be used. In the polymer formed by curing, the Diels-Alder monomer subunits can be illustrated by Formula 1, wherein the starred bonds are to carbon atoms of moieties having reacted with the curing agent, as will be understood by persons of ordinary skill.

A filler may be added to the mixture of substituted Diels-Alder monomer and curing agent to form a composite material. For example, silica (SiO₂) particles with an average or maximum circumference of about 1 μm can be added to form a composite material with polymer 320 and up to about 90 wt. % filler. In some embodiments, the amount of filler is between about 40-50 wt. % or 50-60 wt. %. Other examples of fillers that may be used in some embodiments can include polyhedral oligomeric silsesquioxane (POSS) particles, SiO₂ particles of other sizes (e.g., about 1-50 μm), etc. The silica particles may optionally be functionalized (e.g., with glycidyl groups).

In some embodiments, a thermally latent organic base is included in the mixture as well. This is discussed in greater detail with respect to FIG. 1B. In further embodiments, the underfill can include a radical inhibitor (e.g., butylated hydroxytoluene (BHT), phenothiazine, etc.). This can reduce side reactions that may hinder rehealing (see FIG. 1C).

FIG. 1B is a flow diagram illustrating a process 101 of reworking the underfill formed in process 100, according to some embodiments. A semiconductor device, such as a multi-chip module, containing the underfill can be obtained. This is illustrated at operation 125. A multi-chip module can have a defective chip (or chiplet) to be removed and optionally replaced. A thermal stimulus can be applied in order to soften the underfill. This is illustrated at operation 130. In some embodiments, the thermal stimulus is applied locally at the site of the defective chip. The temperature of the thermal stimulus can vary depending on the properties/structure of the polymer, which may be influenced by the selection of R groups on the substituted Diels-Alder monomer, as discussed above. In some embodiments, the thermal stimulus is between about 90° C. and 120° C.

The defective chip can be removed from the softened underfill. This is illustrated at operation 135. The underfill remaining at the site of the defective chip after its removal can then be removed using a depolymerization mixture. This is illustrated at operation 140. In other embodiments, operation 125 may be omitted, and the defective chip may be removed upon depolymerization of the underfill polymer. In these instances, heat may optionally be applied during treatment with the depolymerization mixture.

The depolymerization reaction can involve transesterification. For example, the depolymerization mixture used in operation 140 can be a solution containing an organic catalyst, an alcohol, and a solvent. For example, the organic catalyst may be an alkyl amine (e.g., triethylamine, Hünig's base, tributylamine, trioctylamine, etc.), an amino alcohol, a stimuli-responsive or heat/light activated catalyst, etc. The alcohol may be, for example, methanol, ethanol, propanol, butanol, etc. Appropriate solvents can include water, an alcohol, an amino alcohol, a diol, or combinations thereof. In some embodiments, one or more of the solvents may be used in combination with N-methyl-2-pyrrolidone (NMP). When amino alcohols are used, the depolymerization mixture may include an alcohol and an amino alcohol serving as both the solvent and the organic catalyst.

A variety of transesterification reactions may be carried out. In further embodiments, the depolymerization may involve an alcoholysis reaction in which the depolymerization mixture includes a base and an alcohol such as methanol, ethanol, isopropanol, etc. The depolymerization reaction may produce a carbonate byproduct in reactions with a base and a diol such as propylene glycol. In another example, the depolymerization may involve glycolysis, e.g., when the depolymerization mixture includes ethylene glycol and triethyl amine (TEA). In additional embodiments, the depolymerization may involve an aminolysis reaction in which the depolymerization mixture includes a base and a primary amine (e.g., CH₃(CH₂)ₙNH₂, where n is an integer between 1 and 10).

In embodiments where the underfill includes a thermally latent base, such as 2-methyl-1-(phenylsulfonyl) propan-2-yl piperidine-1-carboxylate or an alkylammonium (R₃N⁺) salt of 2-(3-benzoylphenyl) propanoic acid, the depolymerization at operation 140 may be aided by a heat stimulus. Thermal decomposition of the base can release carbon dioxide (CO₂) by decarboxylation reaction, allowing the base molecule to act as a catalyst for the transesterification chemistry when combined with the solvent. In further embodiments, the depolymerization may be carried out in response to pH changes or light exposure, depending on the linkages formed between the −X groups of compound 210 and the curing agent.

Removal of the underfill at operation 140 may allow a new chip to be connected at the site of the removed chip. This is not shown in FIG. 1A.

While discussed in the context of underfills, processes 100, 101, and 102 may be used for other applications, such as other packaging materials (e.g., TIMs, adhesives, etc.).

FIG. 1C is a flow diagram illustrating a process 102 of rehealing the underfill formed in process 100, according to some embodiments. A semiconductor device containing the underfill can be obtained. This is illustrated at operation 145. The underfill may have cracks, voids, or other defects that can affect one or more chips in the device. Therefore, a heat stimulus can be applied in order to soften the underfill. This is illustrated at operation 150. Operation 150 can include raising the temperature (e.g., to about 90-120° C.) of the underfill. When the temperature of the underfill is raised (e.g., for about 30 min.), reverse dimerization of the cyclopentadiene moieties can occur, thereby “softening” the polymer. In some embodiments, the underfill can include a radical inhibitor that may reduce side reactions while the polymer is softened.

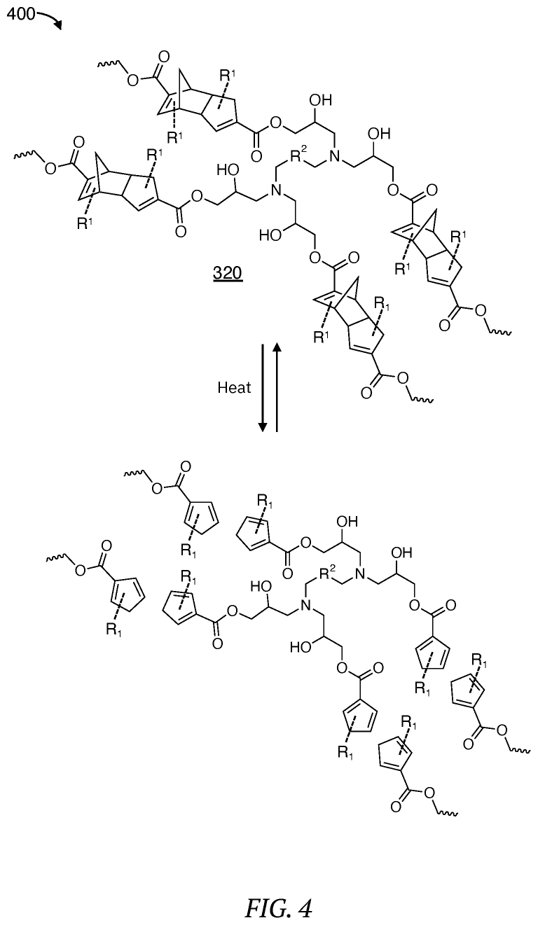

The thermal stimulus can be removed, allowing the chip/underfill to return to operating temperature. This is illustrated at operation 155. As the temperature of the underfill decreases, the cyclopentadiene moieties can dimerize again, thereby “healing” the polymer. An example showing reverse dimerization and re-dimerization of the polymer is illustrated in FIG. 4.

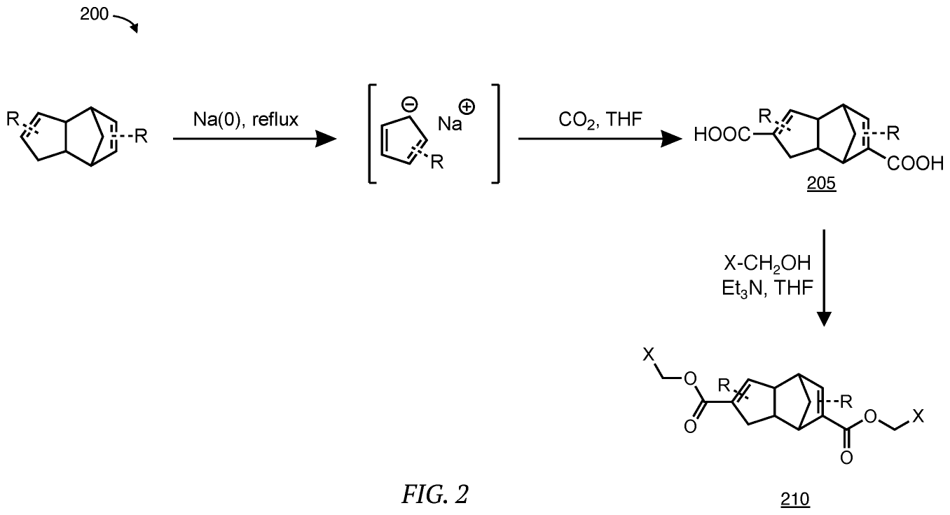

FIG. 2 is a chemical reaction diagram illustrating a process 200 of forming a monomer with ester moieties and thermally reversable Diels-Alder dimer moieties (“substituted Diels-Alder monomer”), according to some embodiments. The monomer can be an example of the monomer provided at operation 110 of process 100 (FIG. 1A). In process 200, an R-substituted dicyclopentadiene can be refluxed with sodium (Na (0)) to form a sodium substituted-cyclopentadienide (Na⁺[R-Cp⁻]) intermediate, which can be reacted with carbon dioxide (CO₂) in a tetrahydrofuran (THF) solution to form an R-substituted dicyclopentadiene-dicarboxylic acid 205.

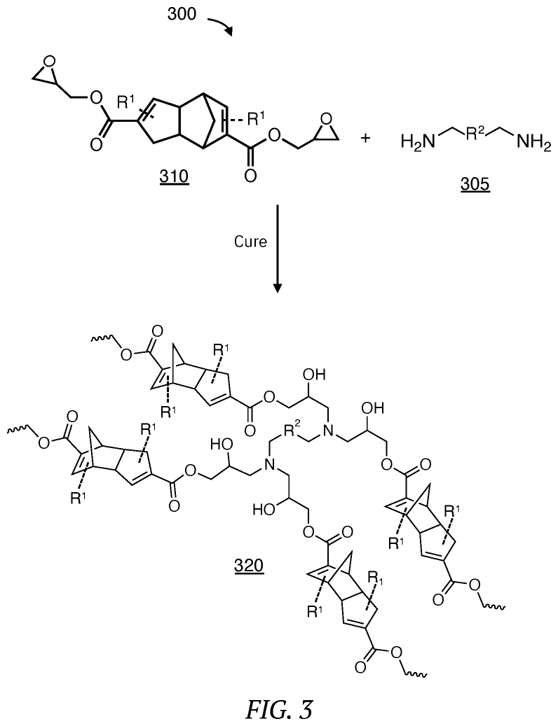

The R-substituted dicyclopentadiene-dicarboxylic acid 205 can be reacted with an X-substituted organic compound having a hydroxyl moiety (X—CH₂OH), where X includes a reactive (polymerizable) group, such an epoxy, styrene, α,β-unsaturated carbonyl, aziridine, dicarbonyl, etc. The X ligand may one or more additional reactive or unreactive moieties. Process 200 can form the substituted Diels-Alder monomer 210 with ester groups containing the —CH₂X moiety (at the starred bonds in Formula 1) from a reaction with X—CH₂OH. For example, X—CH₂OH may be glycidol (2,3-epoxy-1-propanol). In these instances, the substituted Diels-Alder monomer 210 can have glycidyl ester moieties (see FIG. 3).

FIG. 3 is a chemical reaction diagram illustrating a process 300 of forming a polymer for underfills or other packaging materials, according to some embodiments. Process 300 can be an example of the curing reaction at operation 115 of process 100 (FIG. 1A). In process 300, an amine curing agent 305 can be added to a substituted Diels-Alder monomer 310. The R¹ groups of the substituted Diels-Alder monomer 310 are equivalent to the R groups illustrated in FIG. 2 and Formula 1. The illustrated monomer 310 can be an example of monomer 210 formed using glycidol in process 200.

The addition of the curing agent 305, followed by curing, can result in a polymer 320 that may be used in electronic packaging materials (e.g., as an underfill, TIM, adhesive, etc.). Polymer 320 has thermally reversible dicyclopentadiene moieties that can allow rehealing when a heat stimulus is applied (see FIGS. 1C and 4). Polymer 320 also has ester moieties that can allow reworking (e.g., removal of the underfill followed by removal and/or replacement of the corresponding chip). This is discussed in greater detail with respect to FIGS. 1B and 4.

The illustrated amine curing agent 305 includes two primary amine moieties (—NH₂) bound to carbon atoms from organic moieties that form the remainder of the molecular structure of the amine curing agent 305. These organic moieties are represented generically by R² in FIG. 2 and depend on the type of curing agent used, as will be understood by those of ordinary skill in the art. The amine curing agent 305 may be any appropriate curing/hardening agent for epoxy resins. In some embodiments, the amine curing agent 305 can be a curing agent commonly used in, for example, commercially available resins such as Stycast® 1266 (manufactured by Henkel AG & Co., KGaA) or SUMIRESIN EXCEL® CRP-4160G (Sumitomo Bakelite Co., Ltd.) (“4160G hardener”). In some embodiments, the amine curing agent 305 is 4,7,10-trioxatridecane-1,13-diamine or 4,4-methylenebis(2-ethylaniline).

Polymer 320 may be produced using conventional reaction conditions for epoxy resin formation. For example, curing may take place at temperatures of about 60° C., 90° C., 100° C., 120° C., etc., depending on the reagent selection. A filler may be added to the mixture of substituted Diels-Alder monomer 310 and curing agent 305 to form a composite material. In some embodiments, process 300 may form an underfill using 4160G hardener as the amine curing agent 305 and glycidyl-functionalized silica particles with a median size distribution of 1.5 μm as a filler. In this embodiment, the R¹ groups on the Diels-Alder monomer 310 may be methyl, although other R¹ groups may be used. This mixture of substituted Diels-Alder monomer 310, amine curing agent 305, and filler may be cured at about 100° C. for approximately 2 hours in a nitrogen atmosphere. The resulting underfill may be rehealed or reworked as shown in FIGS. 3 and 4.

Additional examples of reaction conditions, underfill components, and monomer 310 structures (e.g., R¹ groups) that may be used in process 300 are discussed above with respect to FIG. 1A.

FIG. 4 is a chemical reaction diagram illustrating a process 400 of rehealing polymer 320, according to some embodiments. Upon applying a heat stimulus to the polymer or a material containing the polymer, the Diels-Alder units can undergo reverse dimerization. This can cause the polymer/material to soften, which may allow rehealing of defects in the material. Upon lowering the temperature (e.g., by removing the heat stimulus), the substituted cyclopentadiene units can re-dimerize. Process 400 illustrates an example of the rehealing discussed above with respect to operations 150 and 155 of process 102 (FIG. 1C).

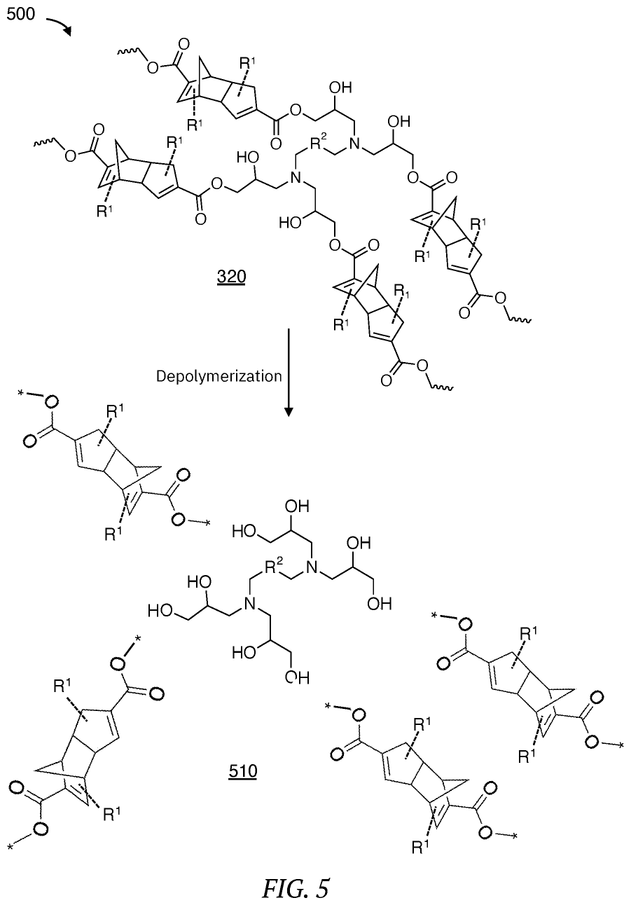

FIG. 5 is a chemical reaction diagram illustrating a process 500 of depolymerizing polymer 320, according to some embodiments. In process 500, cured underfills or other materials containing polymer 320 can be removed from a substrate using a depolymerization mixture suitable for transesterification reactions. The transesterification can result in a monomer solution 510 that can be rinsed away. Various examples of depolymerization mixtures and processes that may be used in process 500 are discussed above with respect operation 140 of process 101 (FIG. 1B).

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A composition, comprising:
an underfill, wherein the underfill comprises:
a polymer having monomer units with substituted Diels-Alder moieties and ester moieties.

2. The composition of claim 1, wherein the underfill further comprises a filler.

3. The composition of claim 1, wherein the underfill further comprises a thermally latent base.

4. The composition of claim 1, wherein the monomer units have the following structure: 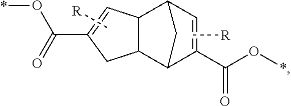
wherein:
each starred bond is to a carbon atom of the polymer; and
each R is an organic substituent.

5. The composition of claim 4, wherein the organic substituent comprises an alkyl group.

6. A process, comprising:
obtaining an underfill, the underfill comprising:
a polymer having monomer units with substituted Diels-Alder moieties and ester moieties.

7. The process of claim 6, wherein the underfill is a composite material.

8. The process of claim 6, further comprising healing a defect in the underfill by applying a thermal stimulus to the underfill.

9. The process of claim 6, further comprising removing the underfill from a surface by treating the polymer with a solution comprising reagents for depolymerization.

10. The process of claim 9, wherein the reagents comprise an organic catalyst, an alcohol, and a solvent.

11. The process of claim 9, wherein the depolymerization comprises a transesterification reaction.

12. The process of claim 6, wherein the underfill is below at least one chip in a semiconductor device.

13. The process of claim 12, further comprising:
dissolving a layer of the underfill at a location of a selected chip from the at least one chip;
removing the selected chip and the dissolved underfill from the location; and
connecting a new chip at the location.

14. The process of claim 12, further comprising:
applying a thermal stimulus to soften a layer of the underfill at a location of a selected chip from the at least one chip;
removing the selected chip from the softened layer of the underfill;
dissolving the layer of the underfill via transesterification;
removing the dissolved underfill; and
connecting a new chip at the location.

15. The process of claim 12, further comprising healing a defect in a layer of the underfill below a selected chip from the at least one chip by applying a localized thermal stimulus at the selected chip.

16. The process of claim 6, wherein the monomer units have the following structure: 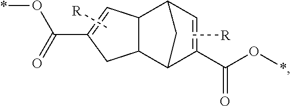
wherein:
each starred bond is to a carbon atom of the polymer; and
each R is an organic substituent.

17. The process of claim 16, wherein the organic substituent comprises an alkyl group.

18. A process, comprising:
providing a mixture, the mixture comprising:
a curing agent; and
a monomer comprising substituted Diels-Alder moieties and ester moieties; and
curing the mixture to form an underfill.

19. The process of claim 18, wherein the monomer has the following structure: 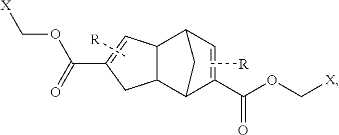
wherein:
each X is a moiety comprising a reactive group; and
each R is an organic substituent.

20. The process of claim 19, wherein each X is a glycidyl moiety.

21. A process, comprising:
providing a semiconductor device comprising an underfill, the underfill comprising:
a polymer having monomer units with substituted Diels-Alder moieties and ester moieties.

22. The process of claim 21, wherein the monomer units have the following structure: 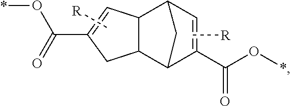
wherein:
each starred bond is to a carbon atom of the polymer; and
each R is an organic substituent.

23. A semiconductor device, comprising:
an underfill comprising a polymer, wherein the polymer comprises:
monomer units with substituted Diels-Alder moieties and ester moieties.

24. The semiconductor device of claim 23, wherein the monomer units have the following structure: 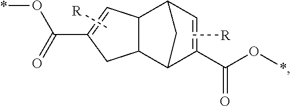
wherein:
each starred bond is to a carbon atom of the polymer; and
each R is an organic substituent.

25. The semiconductor device of claim 23, wherein the semiconductor device comprises a multichip module.
